(19) United States
(12) Patent Application Publication
(10) Pub. No.: US 2007/0013424 A1
(43) Pub. Date: Jan. 18, 2007

(54) Differential dual-edge triggered multiplexer flip-flop and method

(76) Inventor: Muralikumar A. Padaparambil, Poughkeepsie, NY (US)

Correspondence Address: EPSON RESEARCH AND DEVELOPMENT INC;INTELLECTUAL PROPERTY DEPT, 2580 ORCHARD PARKWAY, SUITE 225, SAN JOSE, CA, 95131, US

(21) Appl. No.: 11/184,205

(22) Filed: Jul. 18, 2005

(51) Int. Cl. H03K 3/00

(52) U.S. Cl. 327/199

(57) ABSTRACT

A differential dual-edge triggered multiplexer flip-flop configured and operated to capture a first data signal on one edge of the clock and a second data signal on the other clock edge. By so doing, the output data rate of such a flip-flop is twice that of the input data rate but clocked with half the frequency, as compared to a single-edge triggered flip-flop implementation. This reduction in clock frequency reduces power consumption, as compared to a conventional single-edge triggered flip-flop, for an identical throughput. Such a flip-flop includes two main latches that operate in complementary fashion, that is, when one is holding data, the other is providing data for sampling by the corresponding circuitry in the multiplexer of the flip-flop. In an alternate embodiment, two main latches have both data inputs tied together to accomplish the function of a regular dual-edge triggered flip-flop. In this case, a data signal is sampled and passed to the output of the multiplexer during every clock transition.

### BACKGROUND OF THE INVENTION

1. Field of the Invention

The present invention generally relates to the field of dual-/double-edge triggered flip-flops. More specifically, embodiments of the present invention pertain to systems and architectures of such flip-flop circuits, methods and algorithms of their operation, and communication systems in which such flip-flops are employed.

2. Description of the Related Art

High-speed flip-flops are key components in communication circuits, especially those employed in serial communication systems. For high frequency applications conventional full-swing CMOS flip-flops are typically not used because of concerns regarding high power consumption and high switching noise. In such applications full-swing CMOS circuits are typically replaced with differential circuits performing the same function. Differential circuits are preferred at high frequencies because of certain advantages that they provide, including low switching noise and low power consumption, as compared to full-swing CMOS circuits. A differential dual-/double-edge triggered multiplexer flip-flop samples and passes one of the two input data signals at every clock transition, i.e., at every edge (rising and falling) of the clock. Such flip-flops have application in high-speed implementations of parallel-to-serial conversion circuits known as serializers.

When the data inputs of a differential dual-edge triggered multiplexer flip-flop are tied together, then the function realized is that of a differential dual-edge triggered flip-flop. Such flip-flops find application in retiming circuits in serial communications. A dual-edge triggered flip-flop can output the data presented at its input at a rate of F bps with a input clock frequency of just F/2 Hz., whereas a single-edge triggered flip-flop (full-swing/differential) can pass data only at the rate of the clock speed, i.e., at a rate of F bps for a clock frequency of F Hz. This reduction in clock speed by half for the same data rate directly reduces the power dissipated on the clock line by half, as compared to the conventional scheme. At high speeds, i.e., above 1 GHz, full-swing CMOS circuits consume significant power, and hence a “low swing” implementation of circuits like differential circuits is preferred to reduce power. A differential implementation coupled with the power saving resulting from the halving of the clock frequency for a given throughput makes the implementation of a differential dual-/double-edge triggered flip-flop a very good alternative for high-speed operation.

### SUMMARY OF THE INVENTION

Accordingly, it is an object of the present invention to provide a differential dual-edge triggered multiplexer flip-flop that not only provides these advantages, but also does so with a simple yet reliable architecture.

According to one aspect of the invention, a circuit is provided that comprises first and second latches and a multiplexer. The first latch includes a first data input configured to receive a first input data signal, a first clock input configured to receive a clock signal, and a first data output node on which a first output data signal is generated during a first state of the clock signal; and a first pair of cross-coupled logic inverters configured to hold a last value of the first input data signal during a second state of the clock signal. The second latch includes a second data input configured to receive a second input data signal, a second clock input configured to receive the clock signal, and a second data output node on which a second output data signal is generated during the second state of the clock signal; and a second pair of cross-coupled logic inverters configured to hold a last value of the second input data signal during the first state of the clock signal. The multiplexer includes data inputs configured to receive the first output data signal and the second output data signal, a third clock input configured to receive the clock signal, and a first data output that outputs the first output data signal during the second state of the clock signal and outputs the second output data signal during the first state of the clock signal.

In one embodiment, the first latch is configured such that the first data input comprises a pair of first data inputs configured to respectively receive the first input data signal and its complement, and the first data output node comprises a first pair of data output nodes on which the first output data signal and its complement are respectively generated during the first state of the clock signal. Similarly, in the second latch, the second data input comprises a pair of first data inputs configured to respectively receive the second input data signal and its complement, and the second data output node comprises a second pair of data output nodes on which the second output data signal and its complement are respectively generated during the second state of the clock signal. Also, the multiplexer further comprises a second data output that outputs the complement of the first output data signal during the second state of the clock signal and outputs the complement of the second output data signal during the first state of the clock signal.

Preferably, the first pair of cross-coupled logic inverters comprises a pair of inputs to which the first output data signal and its complement are cross-coupled.

Likewise, the second pair of cross-coupled logic inverters also preferably comprises a pair of inputs to which the second output data signal and its complement are cross-coupled.

The circuit preferably also includes a plurality of pull-up devices, one coupled to each of the first latch, the second latch, and the multiplexer.

In one embodiment of the above-described circuit, the first and second data signals are different data signals, in which case the circuit is a differential dual-edge triggered multiplexer flip-flop.

In another embodiment, the first and second data signals are the same, thereby realizing the function of a regular dual-edge triggered flip-flop.

In another aspect, the invention involves a communication circuit that comprises the above-described differential dual-edge multiplexer flip-flop and/or the regular dual-edge triggered flip-flop.

In another aspect, the invention involves a method for serializing data, comprising receiving a first and second input data signals and a clock signal; generating a first output data signal during a first state of the clock signal; holding a last value of the second input data signal during the first state of the clock signal; generating a second output data signal during the second state of the clock signal; holding a last value of the first input data signal during a second state of the clock signal; and outputting the first output data signal during the second state of the clock signal and outputting the second output data signal during the first state of the clock signal.

In the method, the first and second data signals may be the same or different data signals.

Other objects and attainments together with a fuller understanding of the invention will become apparent and appreciated by referring to the following description and claims taken in conjunction with the accompanying drawings.

### BRIEF DESCRIPTION OF THE DRAWINGS

In the drawings like reference symbols refer to like parts.

FIG. 1(a) is a circuit diagram illustrating a first latch of a dual-edge triggered multiplexer flip-flop in accordance with at least one embodiment of the invention.

FIG. 1(b) is a circuit diagram illustrating a second latch of a dual-edge triggered multiplexer flip-flop in accordance with at least one embodiment of the invention.

FIG. 1(c) is a circuit diagram illustrating a multiplexer of a dual-edge triggered multiplexer flip-flop in accordance with at least one embodiment of the invention.

FIG. 2 is a flow chart illustrating the operation of the dual-edge triggered multiplexer flip-flop shown in FIG. 1.

FIG. 3 shows circuit diagrams illustrating another embodiment of a dual-edge triggered multiplexer flip-flop in accordance with the invention, of which FIG. 3(a) is a circuit diagram of a first latch of such a flip-flop, FIG. 3(b) is a circuit diagram of a second latch of such a flip-flop, and FIG. 3(c) is a circuit diagram of a multiplexer of such a flip-flop.

FIG. 4 is a flow chart illustrating the operation of the flip-flop shown in FIG. 3.

FIG. 5 is a schematic diagram of a communication circuit in which the flip-flop of either FIG. 1 or 3 may be embodied.

### DESCRIPTION OF THE PREFERRED EMBODIMENTS

Reference will now be made in detail to the preferred embodiments of the invention, examples of which are illustrated in the accompanying drawings. While the invention is described in conjunction with the preferred embodiments, it will be understood that such description is not intended to limit the invention to these embodiments. On the contrary, the invention is intended to cover alternatives, modifications and equivalents included within the spirit and scope of the invention as defined by the appended claims. Furthermore, in the following detailed description of the present invention, numerous specific details are set forth in order to provide a thorough understanding of the present invention. However, it will be readily apparent to one skilled in the art in light of the following disclosure that the present invention may be practiced without some or all of these specific details. In other instances, well-known methods, procedures, components, and circuits have not been described in detail so as not to unnecessarily obscure aspects of the present invention.

Some portions of the detailed descriptions that follow are presented in terms of processes, procedures, logic blocks, functional blocks, processing, and/or other symbolic representations of operations on code, data bits, data streams or waveforms within a computer, processor, controller and/or memory. These descriptions and representations are generally used by those skilled in the data processing arts to effectively convey the substance of their work to others skilled in the art. A process, procedure, logic block, function, process, etc., is herein, and is generally, considered to be, a self-consistent sequence of steps or instructions leading to a desired and/or expected result. The steps generally include physical manipulations of physical quantities. Usually, though not necessarily, these quantities take the form of electrical, magnetic, optical, or quantum signals capable of being stored, transferred, combined, compared, and/or otherwise manipulated in a computer or data processing system. It has proven convenient at times, principally for reasons of common usage, to refer to these signals as bits, waves, waveforms, streams, values, elements, symbols, characters, terms, numbers, or the like, and to their representations in computer programs or software as code (which may be object, source, or binary code).

It should be borne in mind, however, that such terms and similar terms are associated with the appropriate physical quantities and/or signals, and are merely convenient labels applied to these quantities and/or signals. The operations and/or processes described herein may refer to the actions or processes of a computer or data processing system, or similar processing device (e.g., an electrical, optical, or quantum computing or processing device or circuit), that manipulates and transforms data represented as physical (e.g., electronic) quantities. The actions and processes may involve manipulating or transforming physical quantities within the component(s) of a circuit, system or architecture (e.g., registers, memories, other such information storage, transmission or display devices, etc.) into other data similarly represented as physical quantities within other components of the same or a different system or architecture.

Furthermore, in the context of this application, the term “coupled to” defines a structure that may include a “wire,” “wiring,” “line,” “conductor,” or the like and that refers to any known structure, construction, arrangement, technique, method and/or process for physically transferring a signal from one point in a circuit to another.

Similarly, for convenience and simplicity, the term “clock signal” is used to refer to any suitable periodic signal.

The present invention provides a differential dual-edge triggered multiplexer flip-flop having a configuration that enables it to capture data on both edges of the clock. By so doing, the output data rate of such a flip-flop is twice that of the input data rate but clocked with half the frequency, as compared to a single-edge triggered flip-flop implementation (both full-swing and differential). This reduction in clock frequency reduces power consumption, as compared to a conventional single-edge triggered flip-flop, for an identical throughput. The flip-flop of this invention includes two main latches that operate in complementary fashion, that is, when one is holding data, the other is providing data for sampling by the corresponding circuitry in the multiplexer of the differential dual-edge triggered multiplexer flip-flop.

Each of the flip-flop components, e.g., first and second latches and multiplexer, is comprised of a plurality of transistors. In the illustrated embodiment, all such transistors are of the NMOS type; however, it will be readily apparent from the disclosure provided herein that such an arrangement is not the only one available. Rather, it will be understood by one skilled in the art that, with certain modifications, any of the flip-flop components may be realized with all PMOS transistors, or a combination of NMOS and PMOS transistors. Indeed, other types of transistors may be used as well consistent with the teaching herein.

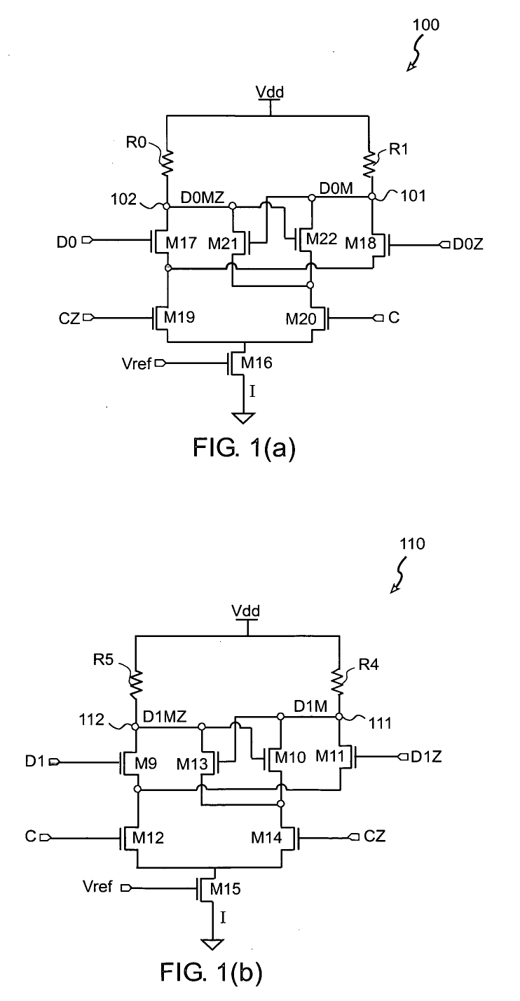

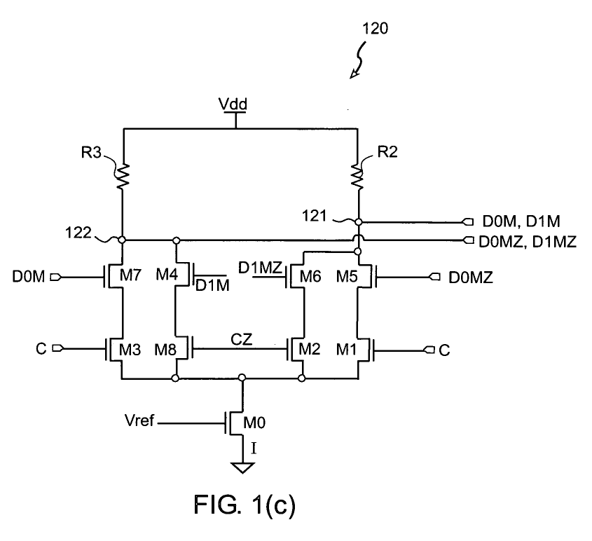

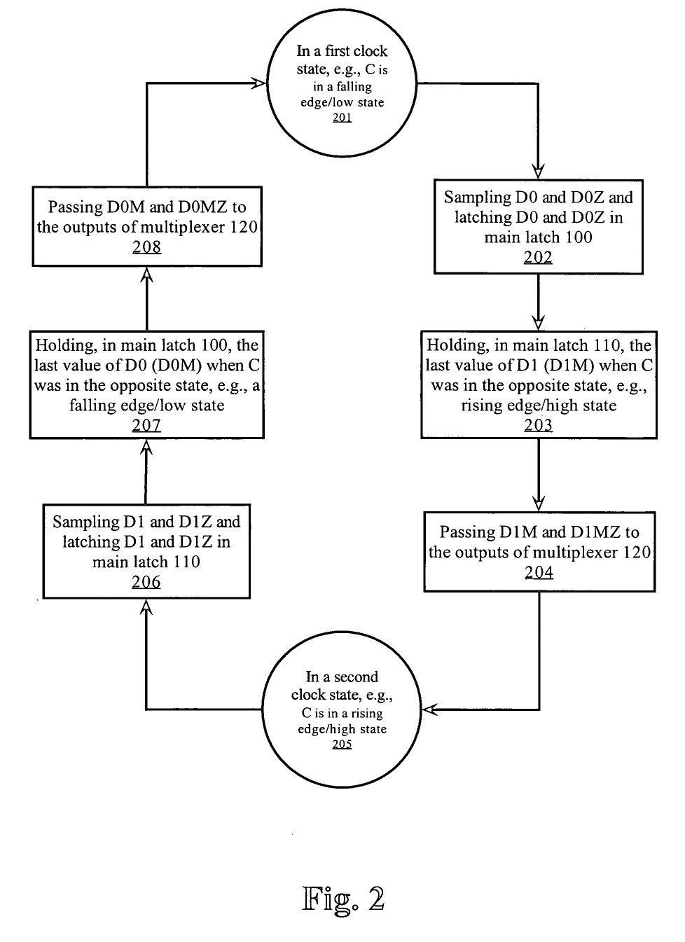

FIG. 1 shows exemplary circuit diagrams of two main latches (FIGS. 1(a) and (b)) and a multiplexer (FIG. 1(c)), which together form a differential dual-edge triggered multiplexer flip-flop according to embodiments of the invention. This flip-flop receives two input data signals D0 and D1 and their corresponding complements D0Z and D1Z, as well as a clock signal C and its complement CZ.

Referring more specifically to FIG. 1(a), the circuit diagram of the main latch for D0 is indicated by the reference numeral 100. First main latch 100 includes a constant current source, which, in the illustrated embodiment, comprises transistor M16, to the gate of which is applied a constant reference voltage Vref, which creates a constant drain current I. The constant current I is selectively steered through each of resistors R0 and R1 to produce a voltage drop proportional to the size of the resistor. When current flows through resistor R0, R1, then the bottom end of that resistor is at logic low (V_{dd}-IR); when no current flows through the resistor, then the bottom end of that resistor is at logic high (V_{dd}), where V_{dd} represents an operating voltage of the flip-flop that is obtained from a suitable power source.

As shown in FIG. 1(a), input data signal D0 is applied to the gate of transistor M17, and the complementary signal D0Z is applied to the gate of transistor M18. Thus, when D0 is at logic high (and D0Z is logic low) transistor M17 is on and transistor M18 is off. In the opposite data logic state, i.e., when D0Z is at logic high (and D0 is logic low) M18 is on and M17 is off. Transistors M19 and M20, the sources of which are coupled to the drain of transistor M16, are turned on and off by CZ and C respectively. When C goes to logic low, transistor M20 turns off; during this time, CZ goes to logic high, and hence M19 turns on. In this state, transistors M17 and M18, whose sources are coupled to the drain of M19, pass D0 and D0Z to output nodes 101 and 102, where D0 and D0Z are latched. The latched data is designated D0M and its complement as D0MZ. When the opposite logic state occurs, that is, when C goes to logic high and CZ goes to logic low, M19 turns off and M20 turns on, main latch 100 holds on to the last value of D0 when C was at logic low through M21 and M22, the gates of which are coupled to output nodes 101 and 102 respectively, and whose sources are coupled to the drain of M20. With this structure, transistors M21 and M22 operating in conjunction with other circuit elements form a pair of cross-coupled logic inverters, with M21 being controlled by latched data signal D0M on output node 101 and M22 being controlled by D0MZ on output node 102.

Structurally, output node 101 is the coupling between the R1 and the drains of transistors M18 and M22, and output node 102 is the coupling between R0 and the drains of transistors M17 and M21. As will be appreciated, this resistive structure forms a pull-up device for main latch 100.

Referring now to FIG. 1(b), the circuit diagram of the main latch for D1 is indicated by the reference numeral 110. Like first main latch 100, second main latch 110 also includes a constant current source. In the illustrated embodiment, this function is performed by transistor M15, the gate of which receives the constant reference voltage Vref, which creates a constant drain current I. The constant current I is selectively steered through each of resistors R4 and R5 to produce a voltage drop proportional to the size of the resistor. When current flows through resistor R4, R5, then the bottom end of that resistor is at logic low (Vdd-IR); when no current flows through the resistor, then the bottom end of that resistor is at logic high (Vdd). Resistors R4 and R5 are coupled to the drains of input transistors M9 and M11 respectively to form a pull-up device for main latch 110.

In main latch 110 input data signal D1 is applied to the gate of transistor M9, and the complementary signal D1Z is applied to the gate of transistor M11. Thus, when D1 is at logic high (and D1Z is logic low) transistor M9 is on and transistor M11 is off. In the opposite data logic state, i.e., when D1Z is at logic high (and D1 is logic low) M11 is on and M9 is off. Transistors M12 and M14, the sources of which are coupled to the drain of transistor M15, are controlled by the clock signals C and CZ respectively. When C goes to logic high, transistor M12 turns on; during this time, CZ goes to logic low, and hence M14 turns off. In this logic state, transistors M9 and M11, whose sources are coupled to the drain of M12, pass D1 and D1Z to output nodes 111 and 112, where D1 and D1Z are latched. The latched data is designated D1M and its complement as D1MZ. When the opposite logic state occurs, that is when C goes to logic low and CZ goes to logic high, M12 turns off and M14 turns on, main latch 110 holds on to the last value of D1 when C was at logic high through M13 and M10, the gates of which are coupled to output nodes 111 and 112 respectively, and whose sources are coupled to the drain of M14. With this structure, transistors M13 and M10 operating in conjunction with other circuit elements form a pair of cross-coupled, logic inverters, with M13 being controlled by latched data signal D1M on output node 111 and M10 being controlled by D1MZ on output node 112.

Structurally, output node 111 is the coupling between the R4 and the drains of transistors M10 and M11, and output node 112 is the coupling between R5 and the drains of transistors M9 and M13. As will be appreciated, this resistive structure forms a pull-up device for main latch 110.

As will be readily appreciated and understood, main latches 100 and 110 operate in complementary fashion. That is, when one is sampling its input data, the other is holding its last sampled data, and vice versa. Moreover, as previously noted, the main latches operate in conjunction with a multiplexer 120, a circuit diagram of which is shown in FIG. 1(c). The constant current source for circuit 120 is provided by transistor M0, to the gate of which is applied Vref, which creates a constant drain current I for that transistor. The constant current I is selectively steered through each of resistors R2, R3 to produce a voltage drop proportional to the size of the resistor, as explained above in connection with each of the main latches.

In multiplexer 120, when C is at logic high and CZ at logic low, transistors M3 and M1 are on and transistors M2 and M8 are off. Thus, when C goes to logic high, main latch 100 enters the latched mode; thus, latched data D0M and its complement D0MZ are passed to output nodes 121 and 122 of circuit 120. Meanwhile, main latch 110 is sampling its data D1. Then, when the clock logic reverses (C goes to logic low), M3 and M1 turn off and M2 and M8 turn on, main latch 110 changes to the latched mode, and hence latched data D1M and its complement D1MZ are passed to output nodes 121 and 122. During this time, main latch 100 is sampling its data D0.

Thus, on the rising edge of C (that is, when the voltage difference C-CZ goes from negative to positive), D0M is output on 0 and on the falling edge of C (that is, when the voltage difference C-CZ goes from positive to negative), D1M is output on O. Hence, a data signal is sent to the output O on both edges of the clock signal C, thus performing a dual-edge triggered multiplex flip-flop operation.

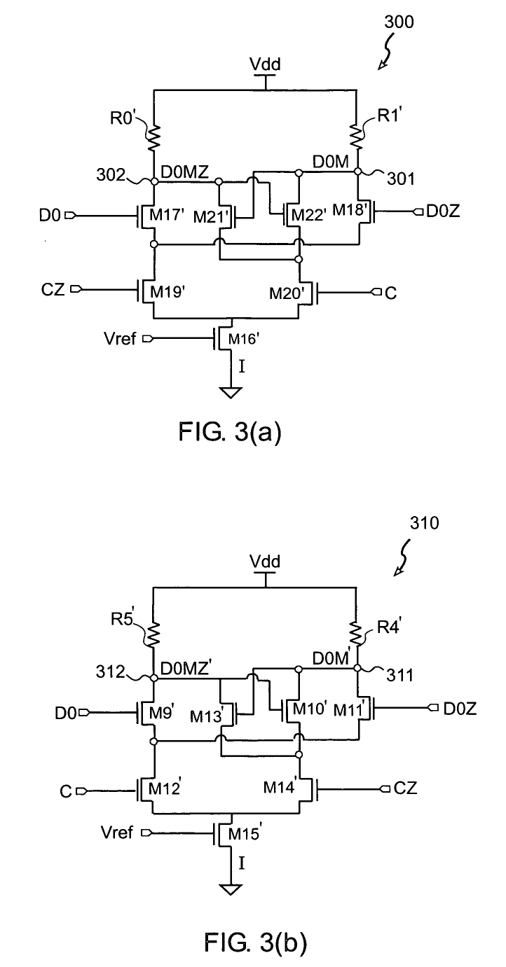

FIG. 2 is a flow chart that further illustrates the operations of the differential dual-edge triggered multiplexer flip-flop according to this embodiment of the invention. During a first clock state 201, e.g., when C is in a falling edge or low state, the following operations occur: sampling input data signal D0 and its complement D0Z and latching D0 and D0Z in main latch 100 (step 202), holding, in main latch 110, the last value of latched data signal D1 (i.e., D1M) when C was in the opposite state, e.g., high or in a rising edge state (step 203), and passing D1M and D1MZ to the outputs of multiplexer 120 (step 204). During a second clock state 205, e.g., when C is in a rising edge or high state, the following operations occur: sampling input data signal D1 and its complement D1Z and latching D1 and D1Z in main latch 110 (step 206), holding, in main latch 100, the last value of latched data signal D0 (D0M) when C was in the opposite state, e.g., low or in a falling edge state (step 207), and passing D0M and D0MZ to the outputs of multiplexer 120 (step 208).

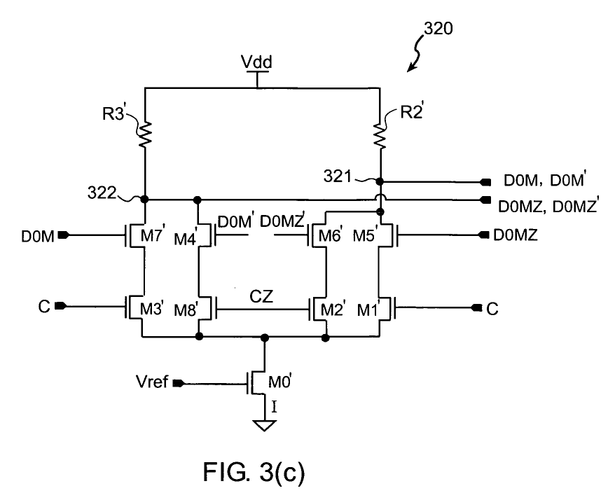

In an alternate embodiment of the invention, two main latches may have both data inputs tied together, as illustrated in the circuit diagrams of FIG. 3, to accomplish the function of a regular dual-edge triggered flip-flop. In this case, D0 and D0Z, which are input to both main latches, are sampled and passed to the outputs of the multiplexer during every clock transition, i.e., rising and falling.

As the circuits of FIG. 1 and 3 are of similar construction, for ease of understanding, the same base transistor and resistor identifiers are used, except in FIG. 3 the prime symbol is added, e.g., M16′.

FIG. 3(a) is a circuit diagram of a first main latch 300 of this flip-flop. It has the same construction as the first main latch 100 illustrated in FIG. 1(a) and operates in the same way. Output nodes 301 and 302 in FIG. 3(a) correspond to output nodes 101 and 102 respectively in FIG. 1(a).

A second main latch 310 of the flip-flop of this embodiment is shown in FIG. 3(b). This second main latch 310 has the same construction as the second main latch 110 shown in FIG. 1(b), but operates in the same way, except that main latch 310 receives as data inputs signals D0 and D0Z, instead of D1 and D1Z, as is the case in FIG. 1(b). In main latch 310 D0 and D0Z are applied to the gates of transistors M9′ and M11′ respectively, and in the latched state, the D0 and D0Z signals are identified as D0M′ and D0MZ′ respectively.

The flip-flop of FIG. 3 further includes a multiplexer 320, as shown in FIG. 3(c), that receives as input signals the latched signals in the main latches 300 and 310. Multiplexer 320 has the same construction as multiplexer 120 in FIG. 1(c), although the input and output signals are different.

In one embodiment of the arrangement shown in FIG. 3, the two main latches 300 and 310 and multiplexer 320 cooperate to sample the data input signals and pass the latched signals to the output nodes 321 and 322 as follows. When C is at logic high and CZ at logic low, transistors M3′ and M1′ are on and transistors M2′ and M8′ are off. Thus, as C goes to high, main latch 300 enters the latched mode; thus, latched data D0M and its complement D0MZ are passed to output nodes 321 and 322 of circuit 320. Meanwhile, main latch 310 is sampling its data D0. Then, when the clock logic reverses (C goes to logic low), M3′ and M1′ turn off and M2′ and M8′ turn on, main latch 310 changes to the latched mode, and hence latched data D0M′ and its complement D0MZ′ are passed to output nodes 321 and 322. During this time, main latch 300 is sampling its data D0.

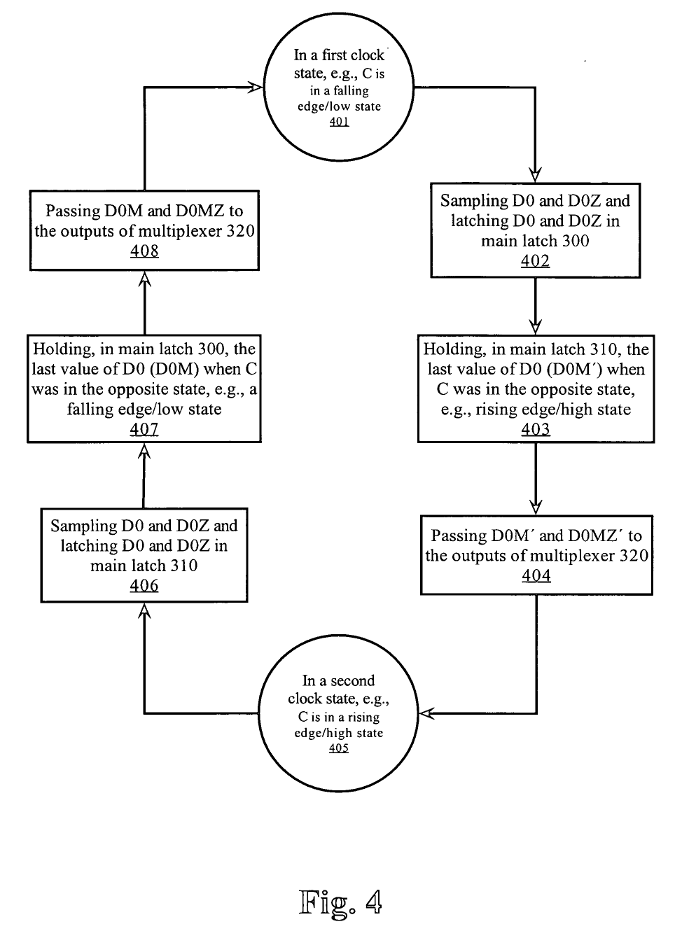

The flow diagram of FIG. 4 further explains the operation of the flip-flop of FIG. 3. When C is in a falling edge or low state, D0 and D0Z are sampled and latched in main latch 300 (step 402). Meanwhile, the other latch, main latch 310, holds the last value of its latched input data D0M′ when C was in the opposite state (step 403). During this state, D0M′ and D0MZ′ are passed to the outputs of multiplexer 320. Then, when C is in a rising edge or high state (step 405), D0 and D0Z are sampled and latched in main latch 310 (step 406). Meanwhile, the other latch, main latch 300, holds the last value of its latched input data D0M when C was in the opposite state (step 407). During this state, D0M and D0MZ are passed to the outputs of multiplexer 320 (step 408).

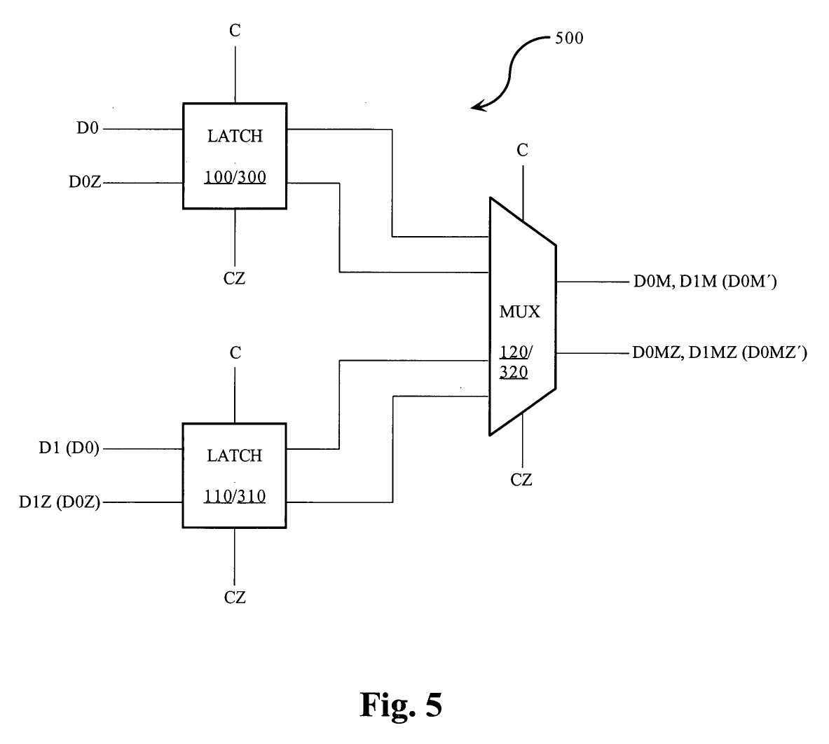

FIG. 5 is schematic diagram of a communication circuit 500 that can include one or more of either of the flip-flops of FIGS. 1 or 3. As shown in the figure, each flip-flop has two latches 100/300 and 110/310 and a multiplexer 120/320.

It should be noted that in any of the above-described embodiments, the transistors employed in connection with Vref are used simply to provide a constant current source for each of the various components of the particular flip-flop circuit. In the context of this invention, performance of this function is not limited to the illustrated arrangement. Rather, any suitable implementation of a constant current source can be used.

More generally, the foregoing descriptions of specific embodiments of the present invention have been presented for purposes of illustration and description. They are not intended to be exhaustive or to limit the invention to the precise forms disclosed. As will be recognized by one skilled in the art, many modifications and variations are possible in light of the above teaching. The embodiments were chosen and described in order to best explain the principles of the invention and its practical application, to thereby enable others skilled in the art to best utilize the invention and various embodiments with various modifications as are suited to the particular use contemplated. It is intended that the scope of the invention be defined by the claims appended hereto and their equivalents.

What is claimed is:

1. A circuit, comprising:
a first latch including
a first data input configured to receive a first input data signal, a first clock input configured to receive a clock signal, and a first data output node on which a first output data signal is generated during a first state of the clock signal, and
a first pair of cross-coupled logic inverters configured to hold a last value of the first input data signal during a second state of the clock signal;
a second latch including
a second data input configured to receive a second input data signal, a second clock input configured to receive the clock signal, and a second data output node on which a second output data signal is generated during the second state of the clock signal, and
a second pair of cross-coupled logic inverters configured to hold a last value of the second input data signal during the first state of the clock signal; and
a multiplexer including data inputs configured to receive the first output data signal and the second output data signal, a third clock input configured to receive the clock signal, and a first data output that outputs the first output data signal during the second state of the clock signal and outputs the second output data signal during the first state of the clock signal.

2. The circuit of claim 1, wherein
in the first latch, the first data input comprises a pair of first data inputs configured to respectively receive the first input data signal and its complement, and the first data output node comprises a first pair of data output nodes on which the first output data signal and its complement are respectively generated during the first state of the clock signal;
in the second latch, the second data input comprises a pair of first data inputs configured to respectively receive the second input data signal and its complement, and the second data output node comprises a second pair of data output nodes on which the second output data signal and its complement are respectively generated during the second state of the clock signal; and
the multiplexer further comprises a second data output that outputs the complement of the first output data signal during the second state of the clock signal and outputs the complement of the second output data signal during the first state of the clock signal.

3. The circuit of claim 2, wherein the first pair of cross-coupled logic inverters comprises a pair of inputs to which the first output data signal and its complement are cross-coupled.

4. The circuit of claim 3, wherein the second pair of cross-coupled logic inverters comprises a pair of inputs to which the second output data signal and its complement are cross-coupled.

5. The circuit of claim 1, further comprising a plurality of pull-up devices, one coupled to each of the first latch, the second latch, and the multiplexer.

6. The circuit of claim 1, wherein the first and second data signals are different data signals.

7. The circuit of claim 1, wherein the first and second data signals are the same.

8. A differential dual-edge triggered multiplexer flip-flop comprising the circuit of claim 6.

9. A communication circuit comprising the differential dual-edge multiplexer flip-flop of claim 8.

10. A communication circuit comprising the circuit of claim 7.

11. A method for serializing data, comprising:
receiving a first and second input data signals and a clock signal;
generating a first output data signal during a first state of the clock signal;
holding a last value of the second input data signal during the first state of the clock signal;
generating a second output data signal during the second state of the clock signal;
holding a last value of the first input data signal during a second state of the clock signal; and
outputting the first output data signal during the second state of the clock signal and outputting the second output data signal during the first state of the clock signal.

12. The method of claim 11, wherein the first and second data signals are different data signals.

13. The method of claim 11, wherein the first and second data signals are the same.
